(19) United States
(12) Patent Application Publication
(10) Pub. No.: US 2016/0120068 A1
(43) Pub. Date: Apr. 28, 2016

(54) HEAT SPREADING TAPE

(71) Applicant: 3M INNOVATIVE PROPERTIES COMPANY, Saint Paul, MN (US)

(72) Inventors: Pei Tien, Taipei (TW); Mihee Lee, Guynggi-Do (KR); Chao-Yuan Wang, Taipei (TW); Han-Yi Chung, Taoyuan City (TW); Ching-Yi Liu, Taipei (TW); Kuo-Chung Lin, Zhongi City (TW); Wei-Yu Chen, Taipei City (TW)

(21) Appl. No.: 14/890,389

(22) PCT Filed: May 12, 2014
(86) PCT No.: PCT/US2014/037647

§ 371 Date: Nov. 10, 2015

(30) Foreign Application Priority Data
May 13, 2013 (CN) 201310174326.1

(51) Int. Cl. H05K 7/20; B32B 7/12; B32B 15/20; B32B 3/30; B32B 9/00; B32B 15/08; B32B 7/02; B32B 5/18

(52) U.S. Cl. CPC H05K 7/20481; B32B 7/02; B32B 7/12; B32B 5/18; B32B 3/30; B32B 9/007; B32B 15/08; B32B 15/20; B32B 2457/00; B32B 2266/02; B32B 2307/302; B32B 2307/304; B32B 2405/00

(57) ABSTRACT

The present invention provides a heat spreading tape including at least one heat spreading layer adapted for heat dissipation and at least one heat insulating layer adhesively attached to the heat spreading layer. Void regions are formed in the at least one heat insulating layer and are adapted for acting as heat transfer barriers in a direction perpendicular to the major surfaces of the heat spreading tape, i.e. the thickness tape.

### FIELD OF THE INVENTION

The present invention generally relates to the field of heat dissipation, and in particular, to a kind of heat spreader.

### BACKGROUND OF THE INVENTION

Currently, with the development of computer technology, the trend of computer development is to develop lighter and thinner products. For example, tablets and notebooks are becoming more and more popular due to their smart appearances. As these products become smaller in size, heat dissipation is always one considerable aspect.

A heat spreader is a heat exchanger that transfers heat between a heat source and a secondary heat exchanger, whose surface area and geometry are more favorable in heat dissipation than the heat source. Through the heat spreader, the heat generated by the heat source “spreads out” to the secondary heat exchanger, such that, it is good for elimination of heat accumulation in the heat source. Accordingly, the combination of the heat spreader and secondary heat exchanger on the heat source contributes to heat dissipation for these products.

Due to its high thermal conductivity, graphite is one material commonly used to make a heat spreader. The thermal conductivity of graphite is typically anisotropic, with the thermal conductivity in X-Y direction, i.e. the X-Y plane of a graphite film, being about 400 to 4,000 W/m·K. The thermal conductivity in the Z-direction, i.e. through the graphite film thickness, is lower, being about 40 W/m·K.

Graphite tape, when use as the heat spreader, is usually applied on a hot spot of a device (such as a tablet or notebook) to remove the heat quickly. A design and application of a conventional heat spreading graphite tape is shown in FIG. 1. This tape includes three layers; an insulation layer 1, a graphite layer 2, and, an adhesive layer 3. When in use, as shown in FIG. 2, the insulation layer 1 is provided at a hot spot 8, the middle, graphite layer 2 is responsible for transferring heat from the hot spot 8 and the adhesive layer 3 is laminated on a outer shell 9 of the tablet or notebook. In order to quickly remove heat from the hot spot 8 and, at the same time, prevent users from feeling that the tablet or notebook surface is hot when they touch the outer shell 9, the heat spreading tape is often arranged to focus on heat transference in the X-Y directions, while achieving suitable heat “insulation” in the Z-direction (see FIG. 1). That is, as shown in FIGS. 1 and 2, heat transferences in the X-direction and the Y-direction are implemented in a smooth and effective manner, which is helpful to dissipate heat from the hot spot 8. Heat transfer in the Z-direction, i.e. the direction perpendicular to the major surfaces of the tape, is inhibited, due to the low Z-direction thermal conductivity of the graphite. The combined high X-Y thermal conductivity and low Z-direction thermal conductivity results in lower heat transfer to outer shell 9 and users will not feel that the tablet or notebook surface is hot when they touch the outer shell 9.

In addition, metals like Cu are also commonly used as material for heat spreaders. Accordingly, it is desired to develop a heat spreading tape with a directional, i.e. anisotropic, heat dissipation structure (i.e., efficient heat dissipation in the X-Y directions while acting as a heat transfer barrier in the Z-direction, i.e., the direction perpendicular to the major surfaces of the tape.

### SUMMARY OF THE INVENTION

It is one object of the present invention to provide a heat spreading tape having an anisotropic heat dissipation structure, i.e., good heat dissipation in the X-Y directions, while acting as a heat transfer barrier in the Z-direction, i.e., the direction perpendicular to the major surfaces of the tape of the tape).

According to one aspect of the present invention, there is provided a heat spreading tape comprising a heat spreading layer and a heat insulating layer which is adhesively attached to the heat spreading layer, wherein the heat insulating layer comprises at least one polymeric region and at least one void region formed in and defined by the polymeric region. The at least one void region is

adapted for acting as heat transfer barriers in the heat insulating layer.

### BRIEF DESCRIPTION OF THE DRAWINGS

These and/or other aspects and advantages of the invention will become apparent and more readily appreciated from the following description of the embodiments of the present invention, taken in conjunction with the accompanying drawings of which:

FIG. 1 is a schematic view of a prior art heat spreading graphite tape;

FIG. 2 is schematic view of the prior art heat spreading graphite tape applied between the outer shell of a tablet/notebook/smart phone/TV and a hot spot;

FIG. 3 is a schematic view of a heat spreading tape according to a first embodiment of the present invention;

FIG. 3a is a schematic view of an alternative heat spreading tape according to the first embodiment of the present invention;

FIG. 4 is schematic view of the heat spreading tape according to the first embodiment of the present invention applied between the outer shell of the tablet/notebook/smart phone/TV and the hot spot;

FIG. 5 is a schematic view of a heat spreading tape according to a second embodiment of the present invention;

FIG. 6a to FIG. 6c schematically show various heat insulating layers that may be used in the heat spreading tapes of the present invention;

FIGS. 7a and 7b schematically show alternative heat insulating layers that may be used in the heat spreading tapes of the present invention;

FIG. 8 is a schematic view of a heat spreading tape according to a third embodiment of the present invention;

FIG. 9 shows schematic view of a foam layer that may be used in the heat spreading tapes of the present invention; and

FIG. 10 is a schematic view of a heat spreading tape according to a fourth embodiment of the present invention.

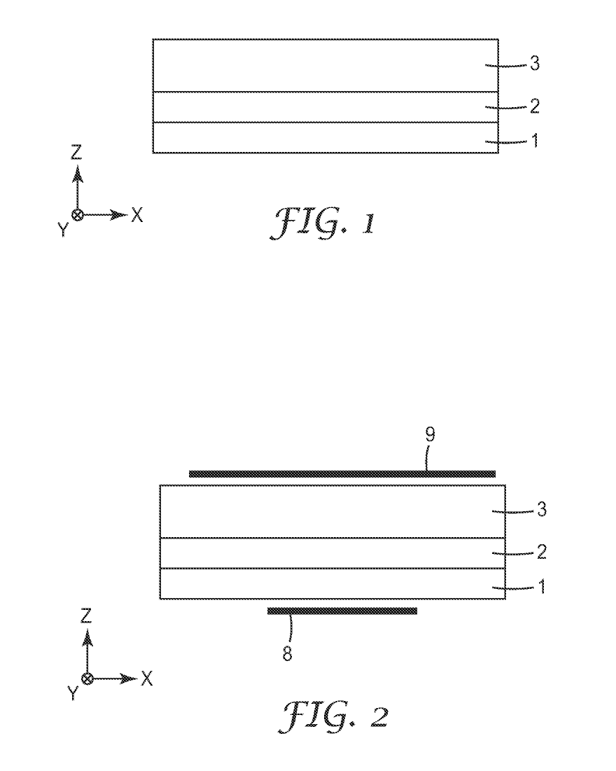

The scope of the present invention will in no way be limited to the drawings, the number of constituting components, the materials thereof, the shapes thereof, the relative arrangement thereof, etc., and are disclosed as an example of an embodiment. These drawings are not drawn to scale. In the drawings, like reference numbers generally indicate identical, functionally similar, and/or structurally similar elements.

### DETAILED DESCRIPTION OF PREFERRED EMBODIMENTS OF THE INVENTION

Some embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

The present invention provides a heat spreading tape including at least one heat spreading layer, adapted for heat dissipation, and at least one heat insulating layer adhesively attached to the heat spreading layer. At least one void region is formed in the heat insulating layer and is adapted for acting as a heat transfer barrier in the heat insulating layer. In some embodiments, the heat insulating layer may include a plurality of polymeric regions and/or a plurality of void regions. The void region(s) may include one or more gases, e.g. air, nitrogen, and carbon dioxide. The structure of the void region(s) is not limited and may include gaps, channels, pores, holes, grooves and the like. The structure of the void region(s) may include combinations of different structures, e.g. grooves and pores.

According to one aspect of the present invention, the heat spreading tape may further comprise a protection layer being attached to the heat spreading layer. In some embodiments, for example, the protection layer may be embodied as an electrical insulating layer. According to another aspect of the present invention, the heat spreading tape may further comprise a protection layer being attached to the heat insulating layer. In some embodiments, for example, the protection layer may be embodied as a second heat insulating layer.

According to one aspect of the present invention, the heat insulating layer can include at least one polymeric region and at least one void region formed in and defined by said polymeric region. Preferably, a plurality of polymeric regions and a plurality of void regions are provided. The polymeric region may include adhesive. According to another aspect of the present invention, the heat insulating layer may further include two adhesive sheets, the polymeric region of the heat insulating layer may comprise at least a non-adhesive layer positioned between and adhesively attached to the two adhesive sheets.

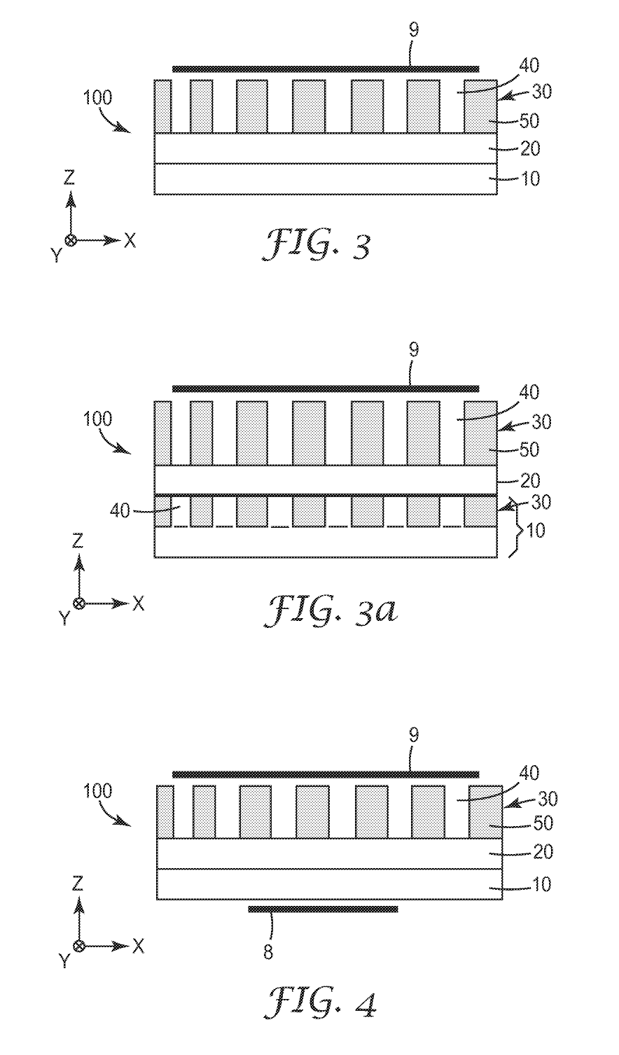

Referring to FIG. 3, heat spreading tape 100 includes a protection layer 10 for support and protection, a heat spreading layer 20 adapted for heat dissipation and a heat insulating layer 30. Heat insulating layer 30 may be formed from a polymeric material, such as an adhesive, and may be attached to the heat spreading layer 20 by its own adhesive properties or by any conventional means, e.g. by an additional adhesive (not shown). According to one aspect of the present invention, heat insulating layer 30 includes void regions 40 formed in and defined by polymeric regions 50 of the heat insulating layer 30. Void regions 40 may include air and are adapted for acting as heat transfer barriers in the heat insulating layer 30. Heat insulating layer 30 usually contains materials having low thermal conductivity, typically from about 0.05 to about 0.2 W/m·K. Air is known to have a low thermal conductivity, typically about 0.023 W/m·K. Therefore, void regions 40, which may include air, provide better “heat transfer barriers” than polymeric regions 50 in the heat insulating layer 30.

The heat spreading layer 20 and heat insulating layer 30 can be combined by using a second adhesive layer (not shown), The heat insulating layer may be fabricated from an adhesive. Heat spreading tape 100 has high thermal conductivity along the surface of heat spreading layer 20, i.e. the X-Y plane of the heat spreading layer, and low thermal conductivity through the heat insulating layer 30, i.e. through the thickness of the tape, because of the lower overall thermal conductivity of the heat insulating layer 30, having void regions 40. According to one aspect of the present invention, the heat spreading tape 100 has high thermal conductivity in X-Y directions, i.e. the X-Y plane, and low thermal conductivity in the Z-direction, i.e., the direction perpendicular to the major surfaces of the tape 100.

In some embodiments, the protection layer 10 may function as a support layer, in the heat spreading tape 100, and may also be an electrical insulating layer. In another embodiment, the protection layer 10 may incorporate a heat insulating layer similar to or the same as those of the heat insulating layer 30. In an alternative embodiment, the protection layer may have a heat insulating layer formed thereon. For example, in the embodiment shown in FIG. 3a, the protection layer 10 has a heat insulating layer 30 with void regions 40, formed therein.

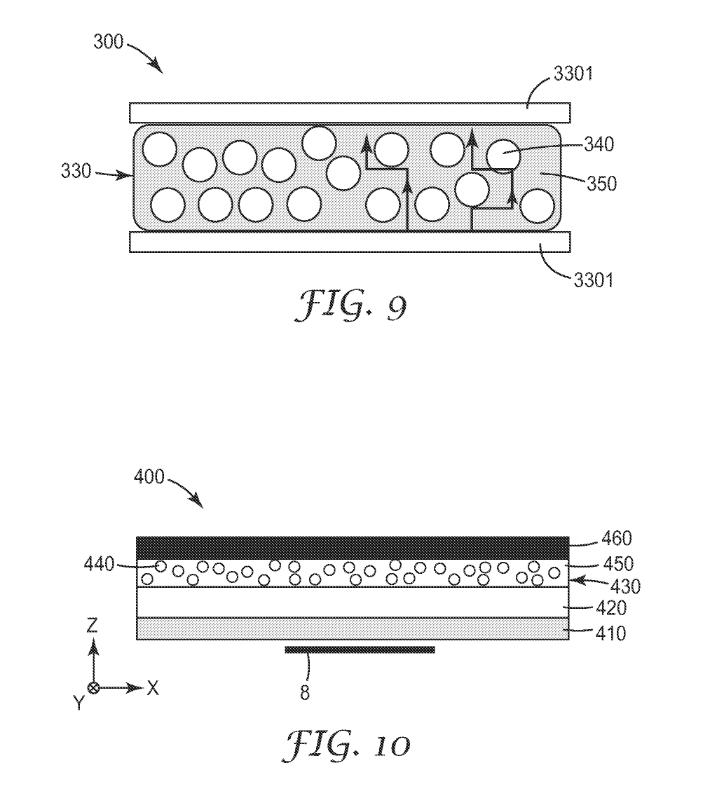

According to one aspect of the present invention, the polymeric region 50 of heat insulating layer 30 can be selected from materials with low thermal conductivity and may be adapted to adhesive bond to other layers. In one aspect, the polymeric region 50 may be an adhesive. The adhesive may be at least one of a thermoset adhesive, pressure sensitive adhesive, thermoplastic elastomer adhesive and hot melt adhesive, pressure sensitive adhesives being preferred. The adhesive may include at least one of rubber adhesive, e.g. rubber pressure sensitive adhesive, acrylic adhesive, polyurethane adhesive, polyimide adhesive, silicone adhesive, epoxy adhesive and combinations thereof. For example, in some embodiments, the adhesive of polymeric region 50, in heat insulating layer 30 in FIG. 3, may be a rubber pressure sensitive adhesive or an acrylic pressure sensitive adhesive. According to another aspect of the present invention, shown in FIG. 9, heat spreading tape 300, the polymeric region of heat insulating layer 330 may include at least a non-adhesive layer 350. Heat insulating layer 330 further includes two adhesive sheets 3301. The non-adhesive layer 350 is positioned between and adhesively attached to the two adhesive sheets 3301. Void regions 340 are formed in the non-adhesive layer 350 and may contain a gas, e.g. air. Non-adhesive layer 350 of the polymeric region of heat insulating layer 330 can be formed from a foam.

It is noted that the structure of void regions 40 may take any possible configuration formed in the heat insulating layer. Examining the embodiments shown in FIG. 3 and FIG. 9, the structure of void regions 40 of heat insulating layer 30 and the structure of void regions 340 of non-adhesive layer 350, respectively, may include, but are not limited to: gaps, channels, pores, holes, grooves, and the like. Void regions may include various combinations of these structures, e.g. grooves and pores. Also, according to the present invention, a total volume of the void regions formed in the heat insulating layer, such as void regions 40 of heat insulating layer 30 of FIG. 3 or void regions 340 of non-adhesive layer 350 of FIG. 9, may range from about 22% to about 90% of the volume of the heat insulating layer. In some embodiments, the total volume of the void regions (e.g. the void regions 40 of the heat insulating layer 30) can range from approximately one third to approximately two third of the volume of the layer in which the void region is formed. In one embodiment, the total volume of the void region 340 formed in the non-adhesive layer 350 can range from approximately 22% to approximately 24% of the volume of the polymeric region of heat insulating layer 430, when a foam material is used. In another embodiment shown in FIG. 10, the volume of a void region 440 can range from approximately 60% to approximately 90% of the total percentage by volume of the foam material, i.e. the heat insulating layer, and the volume of the polymeric region of heat insulating layer 430 can range from approximately 10% to approximately 40%.

According to the present invention, the heat spreading layer may include at least one of metal, ceramic, graphite, graphene, and composite that includes conductive particle and polymer and combinations thereof. For example, the heat spreading layer 20 in FIG. 3 may be a metal layer, e.g. a metal foil or metal film. In some embodiments, the heat spreading layer may be a Cu metal layer. In another embodiment, the heat spreading layer may be an Al metal layer.

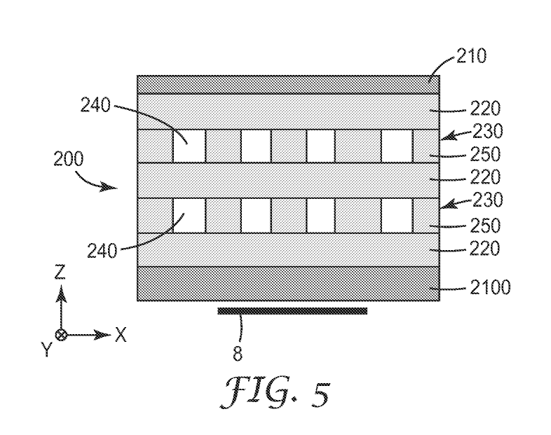

According to the present invention, the heat spreading tape may include a plurality of heat spreading layers and/or a plurality of heat insulating layers. The plurality of heat spreading layers and/or the plurality of heat insulating layers are alternately arranged with each other, such that there is at least one heat insulating layer with the air structures, provided in the heat spreading tape. For example, in the embodiment shown in FIG. 5, the heat spreading tape 200 includes three heat spreading layers 220 and two heat insulating layers 230, which may be adhesive, alternately arranged with one another. Void regions 240 are formed in the two heat insulating layers 230, respectively.

According to the present invention, a total thickness of the heat spreading tape is from about 0.01 mm to about 0.4 mm. According to some embodiments of the present invention, the total thickness of the heat spreading tape is preferably from about 0.0.05 mm to about 0.2 mm.

The followings refer to several embodiments of the present invention.

### First Embodiment

Referring to FIGS. 3 to 4, a first embodiment of the heat spreading tape 100 is provided. Specifically, as shown in FIG. 3, the heat spreading tape 100 includes a protection layer 10 for support and protection, a heat spreading layer 20 adapted for heat dissipation, and a heat insulating layer 30, which may take the form of an adhesive. The heat spreading layer 20 is positioned between the heat insulating layer 30 and the protection layer 10. Void regions 40, which can be air gaps, are formed in the heat insulating layer 30 and defined by the polymeric regions 50. These air gaps are adapted for acting as heat transfer barriers in the heat insulating layer 30. As shown in FIGS. 3 to 4, the void regions 40 are an array of air gaps formed in the heat insulating layer 30.

According to the first embodiment of the present invention, the heat spreading layer 20 is a graphite layer, which is known as a traditional heat spreading layer and can be selected by those skilled in the art. As previously mentioned, graphite has very good thermal conductivity in the X-Y direction, from about 400 to about 4,000 W/m·K, but has very poor thermal conductivity in the Z-direction, about 40 W/m·K), the Z-direction being through the thickness of the graphite layer. In the first embodiment, the array of void regions 40 is formed in the heat insulating layer 30 provided by this invention. Accordingly, due to the heat transfer barrier caused by the heat insulating layer with corresponding air gaps, less heat will transfer through the heat insulating layer 30 with the array of air gaps, compared to a heat insulating layer without air gaps. Therefore, a heat spreading tape with anisotropic thermal conductivity, i.e. high thermal conductivity in the X-Y directions and low thermal conductivity in the Z-direction, can be achieved.

The protection layer 10 is provided to give flexibility to heat spreading layer 20 which is a graphite layer. Graphite is known to be brittle, therefore a protection layer 10 is usually provided. The protection layer 10 is also chosen as a single thinner tape laminated on the graphite of heat spreading layer 20.

Without limitation to possible application, the heat spreading tape 100 in FIGS. 3 to 4 is preferred to be used to prevent the outer shell of an electronic device from becoming too hot during use. In such application, the heat insulating layer 30 is preferred to adhesively attach to the outer shell 9, as shown in FIG. 4. The protection layer 10 is preferably an electrical insulating layer.

FIG. 4 is schematic view showing the heat spreading tape 100 according to the first embodiment of the present invention applied between the outer shell of the tablet/notebook/smart phone/TV and the hot spot. In such application, the protection layer 10 is the first layer adjacent to hot spot 8. Therefore, the outer shell 9 of a tablet/notebook/smart phone/TV, as shown in FIG. 4, can be protected by the heat spreading tape 100 from becoming too hot.

FIG. 3a shows an alternative example to the first embodiment of this invention. An additional heat insulating layer 30, having void regions 40, is provided between the heat spreading layer 20 and protection layer 10. This example provides extra heat insulation from the protection layer 10 and more flexibility to the heat spreading layer 20, which may be made from graphite material.

In the embodiment shown in FIGS. 3 to 4, heat spreading layer 20 can be a graphite layer, commercially available, with a thickness ranging from about 100 μm to about 200 μm. For example, a type O0S1001 graphite layer commercially available can be used. Protection layer 10 may have a thickness ranging from about 5 μm to about 50 μm, preferably about 15 to 30 μm, and prepared from an adhesive tape. Materials and thickness of these two layers 20 and 10 can also be selected in ways known in a traditional heat spreading tape. The heat insulating layer 30 may have a thickness from about 2 μm to about 200 μm, depending on needs of a particular application, and the demands of the materials (described below) for preparing heat insulating layer 30. However, the above ranges for thickness of each layer are based on the application needs. There is no intention to limit selection for greater or less thickness of each layer when required for a specific application.

Each of protection layer 10, heat spreading layer 20 and heat insulating layer 30 are laminated together to form the heat spreading tape 100. These layers can be adhesively bonded together. This process can be made per that known for a traditional heat spreading tape.

The heat insulating layer 30 may be prepared from adhesive materials with low thermal conductivity. The adhesive may be at least one of a thermoset adhesive, pressure sensitive adhesive, thermoplastic elastomer adhesive and hot melt adhesive, pressure sensitive adhesives being preferred. For example, the adhesive may include at least one of rubber adhesive, e.g. rubber pressure sensitive adhesive, acrylic adhesive, polyurethane adhesive, polyimide adhesive, silicone adhesive, epoxy adhesive and combinations thereof. These materials can be used to prepare heat insulating layer 30 and to form the polymeric region 50. In one example, a type 8003 polymeric acrylic adhesive tape commercially available from 3M Company, St. Paul, Minn. can be used to prepare the heat insulating layer 30. Other alternative choices are also available as discussed above.

Protection layer 10 can be prepared from materials known to those skilled in the art and is commercially available, such as acrylic adhesive tape. For example, it can be prepared from a type 12T16 tape which is commercially available from 3M Company, St. Paul, Minn. In this case, the prepared protection layer 10 may typically have a thickness ranging from about 15 to about 25 μm. However, other suitable polymeric materials and/or adhesive tape known in the art may be used to prepare the protection layer 10. Preferably, protection layer can be prepared from single side adhesive tapes having an electrical insulating feature.

The structure of void regions 40, shown in FIGS. 3 to 4, formed in the heat insulating layer 30 can be a variety of shapes and sizes defined by polymeric regions 50, as desired. For example, the structure of void regions 40 may be gaps, channels, pores, holes, grooves and the like and they may be filled with a gas, e.g. air, nitrogen and carbon dioxide. They can be formed by a punch process, for example, if through holes are to be formed as void regions 40. The width or diameter of void regions 40 may be from about 0.5 mm to about 5 mm, and the height of these through holes or channels may be from about 2 μm to about 200 μm, similar as that of the heat insulating layer 30. In one example described above, when the 8003 type polymer acrylic adhesive tape obtained from 3M Company is used for preparing the heat insulating layer 30 of the through hole as the void regions 40, the thickness of the heat insulating layer 30 can be approximately 30 μm, and the void regions 40 and the polymeric regions 50 can have similar thickness. It should be appreciated that thickness can vary when different materials are selected to prepare the thermal heat insulating layer 30. Furthermore, according to the invention, the total volume of the void regions formed in the heat insulating layer (e.g. the void regions 40 formed in the heat insulating layer 30) can range from approximately 25% to approximately 85% of the volume of the heat insulating layer, which means that the remaining part can be the polymeric regions 50. The total volume of the void regions 40 can be approximately one third of the volume of the thermal heat insulating layer 30, while two third of the volume can be the polymeric regions 50. The total volume of the void regions 40 can vary with its size. In one embodiment, the void regions 40 can be a groove which has height similar to the thickness of the polymeric regions 50 and is parallel with the polymeric regions 50. In this example, the void regions 40, which is a groove, can have the width identical with that of the polymeric regions 50. Optionally, the ratio of the width of the void regions 40 to that of the polymeric regions 50 can range from approximately 1:2 to approximately 2:1. As a result, the total volume of the void regions 40 can range from approximately 33.3% to approximately 66.6% of the volume of the heat insulating layer 30. Furthermore, the width of the groove or other sizes such as aperture of the void regions 40 is not required to be the same, i.e. void regions 40 with different sizes can be arranged in the heat insulating layer 30, thus void regions 40 are formed and defined by the polymeric regions 50 which surround them. Therefore, the polymeric regions 50 should be prepared correspondingly to provide ideal void regions 40. As a result, the description of the void regions 40 can be used to explain the shape, volume and structure of the polymeric regions 50.

Thermal Impedance Evaluation

In order to compare the thermal impedance performance of the prior art heat spreading graphite tape and that of the heat spreading tape 100 according to the first embodiment of the present invention, a thermal impedance evaluation test was performed. In this evaluation, the heat spreading graphite tape 100 with void regions including air, as shown in FIG. 3, was Example 1 and a traditional heat spreading graphite tape, without void regions, was Comparative Example 1. Specifically, Example 1 and Comparative Example 1 both had the same dimensions of 1 inch×1 inch (2.54 cm×2.54 cm) while the Example 1 had air gaps in its adhesive layer. In this test, an ASTM5470-thermal impedance meter available from Long Win Science and Technology Company in Taiwan was used to evaluate the thermal impedance of these Samples. The meter was set at 65 psi and under a temperature of 80° C. for 20 mins. Table 1 shows the results of the thermal impedance comparison between the Example 1 and Comparative Example 1 in this test.

TABLE 1

| | | Thermal |
|---|---|---|
| | Total | Impedance of |
| | Thickness | Z-direction |
| | (μm) | (° C. *cm²/W) |
| Example 1 | 130 | 5.127 |
| Comparative Example 1 | 130 | 4.946 |

From the above, it can be seen that, the thermal impedance of Example 1 is higher than that of Comparative Example 1.

### Second Embodiment

Referring to FIGS. 5 to 7, a heat spreading tape 200 according to the second embodiment of the invention is provided. The heat spreading tape 200 is in a multi-layer configuration. Specifically, the heat spreading tape 200 includes (i) protection layer 210 for support and protection, (ii) three heat spreading layers 220, which may be metal, e.g. Cu metal, adapted for heat dissipation, (iii) two heat insulating layers 230, which may include adhesive, which include polymeric regions 250 and void regions 240 defined by polymeric regions 250, adapted to be heat transfer barriers and for adhesive bonding, and (iv) an adhesive layer 2100 which can be a double coated adhesive tape adapted to attach heat spreading tape 200 on hot spot 8. As shown in FIG. 5, the three heat spreading layers 220 and the two heat insulating layers 230 are alternately arranged with one another. Void regions 240 are formed in the two heat insulating layers 230 as defined by polymeric regions 250 and act as heat transfer barriers in the Z-direction of the heat insulating layer 230. As shown in FIGS. 5 to 7, the void regions 240 may be arrays of air gaps formed in the polymeric material, e.g. adhesive, forming heat insulating layer 230. In other words, the polymeric regions 250 of heat insulating layers 230 can form a structure providing air gaps for the void regions 240. Without limitation to possible application, the heat spreading tape 200 in FIG. 5 is preferred to be used to attach to a hot spot 8 for heat dissipation. In such application, the adhesive layer 2100 can attach to hot spot 8. The protection layer 210 is preferably both an electrical insulating and heat insulating layer, for better protection.

In the second embodiment of the present invention, the heat spreading layers 220 can include Cu metal. As known in prior art, Cu metal has a thermal conductivity of about 386 W/m·K. Accordingly, during use, while heat flows through the heat insulating layers 230 with the void regions 240, which can be air gaps, the heat will not easily transfer to the next heat spreading layer 220. Thus, the user will feel less heat compared to the prior art heat spreading graphite tape. In an alternative embodiment, only one heat spreading layer, e.g. Cu metal, may be used.

The second embodiment of the heat spreading tape 200 has some advantages. First, if Cu metal is used as the heat spreading layers 220, the heat spreading tape 200 is more flexible than a tape in which graphite is used as the heat spreading layer. Second, Cu is less expensive than graphite. Additionally, the thermal conductivity of Cu is high enough to provide good heat dissipation.

Many variations can be made to heat spreading tape 200, illustrated in FIG. 5. For example, the heat spreading tape 200 can have only one heat spreading layer 220, wherein the heat spreading layer is a metal layer and is used for heat dissipation, and one heat insulating layer 230, wherein the heat insulating layer is a polymeric adhesive layer, which acts as a heat transfer barrier and adhesive.

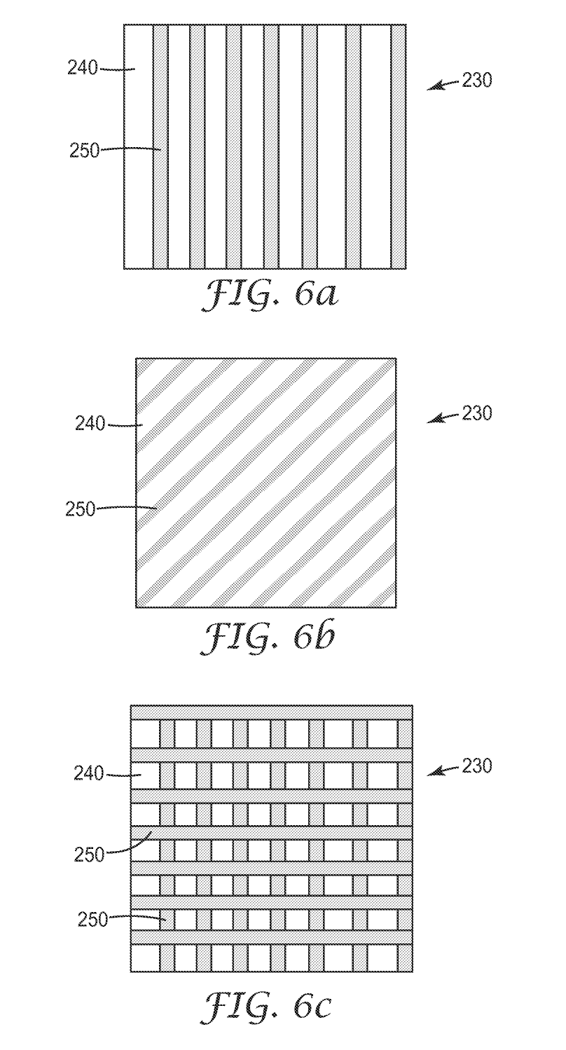

Also, FIG. 6a to FIG. 6c schematically shows various arrangements of void regions 240 defined by polymeric regions 250 in the heat spreading tape 200 according to the second embodiment of the present invention. FIG. 6a schematically shows the void regions 240 as a typical air gap pattern in the heat insulating layers 230, the gaps being in parallel. FIG. 6b schematically shows a similar air gap arrangement in the heat insulating layer 230, with air gaps inclined at about a 45° angle. Also, FIG. 6c shows another type of pattern of air gaps arranged in heat insulating layer 230. In these arrangements, polymeric regions 250 and void regions 240 can have various dimensions to provide different air gaps. For example, either polymeric regions 250 or void regions 240 may have a typical width ranging from about 100 to 200 μm. Polymeric regions 250 and void regions 240 are not necessarily equal, either one may larger or smaller than another. Optionally, the ratio of the width of the void regions 240 to that of the polymeric regions 250 can range from approximately 1:2 to approximately 2:1. As a result, the total volume of the void regions 240 can range from approximately 33.3% to approximately 66.6% of the volume of the heat insulating layers 230. The angle of inclined gaps can also be varied, such as 30°, 15° or others as desired. Alternatively, polymeric regions 250 and void regions 240 are not necessary to be linear and/or continuous, they can be dotted line or curved as well (not shown).

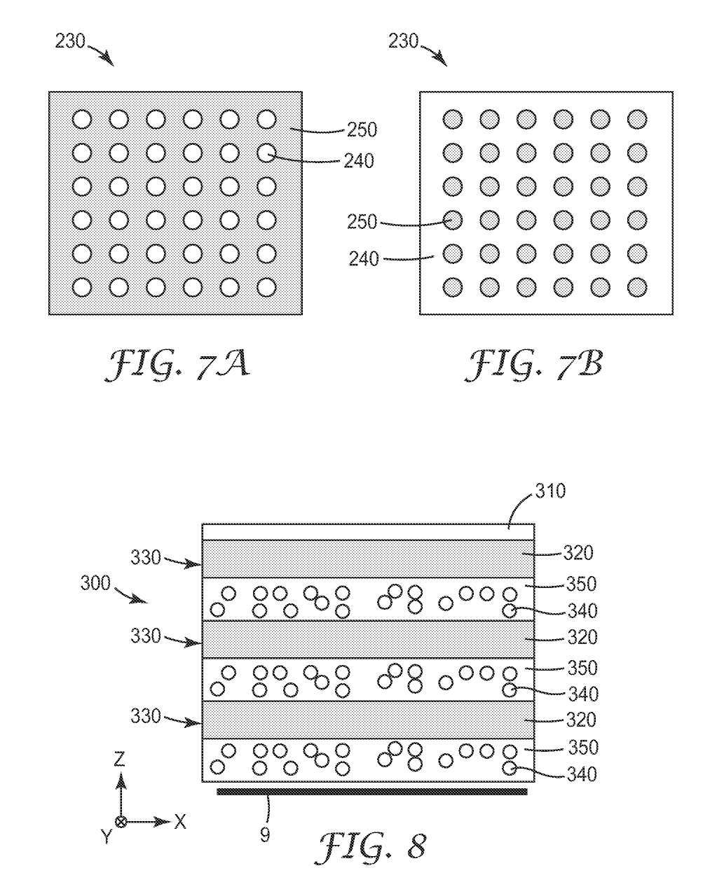

FIGS. 7a and 7b schematically shows alternative arrangements of void regions 240 defined by polymeric regions 250 in heat insulating layer 230 of heat insulating tape 200 of the second embodiment of the present invention. Void regions 240 can be individual holes, shown as white circles in FIG. 7a, or can be a continuous region, as shown by the white area in FIG. 7b. The dark area of both FIG. 7a and FIG. 7b shows the polymeric regions 250 in heat insulating layer 230. Also, it is understandable that void regions 240 and polymeric regions 250 in FIGS. 7a and 7b may have different size and shape, such as holes having dimensions ranging from about 100 to about 300 μm for void regions 240 in FIG. 7a and spots having dimensions ranging from about 100 to about 300 μm for polymeric regions 250 in FIG. 7b. Void regions 240 and polymeric regions 250 are not necessarily identical or be one specific shape. They can be in the shape of circle, square, star, triangle or others. These examples are just for illustrative purposes of the invention and are not to limit the scope of the invention.

The volume percentage of void regions and the polymeric regions can vary according to the application requirements. For example, the volume of the void regions can be changed by adjusting the sizes of the void regions such as aperture and gap width. Therefore, the total volume of the void regions 240 can be changed accordingly. The volume percentage of the void regions 240 in the heat insulating layers layers 230 can range from approximately 25% to approximately 85% of the volume of heat insulating layers 230, particularly from approximately 33.3% to approximately 66.6%, or even more than or less than the percentage shown in the examples of FIG. 7a and FIG. 7b. The volume percentage of the void regions can be 50% or close to 50%, as shown in the example of FIG. 6a. The volume percentage can be changed as required. Also, understandably the polymeric regions are correspondingly prepared to provide the necessary void regions. Thus, the shape, volume and structure of the polymeric regions can be dependent on the required void regions.

In addition, explanation of the invention above and other characteristics and changes of the void regions in first embodiment and the second embodiment can be properly applied to this embodiment, which can be appreciated by those skilled in the art. For example, the void regions 240 can have the thickness identical with that of the heat insulating layers 230.

Table 2 shows an example constitution of the layers of the heat spreading tape 200 according to the second embodiment of the present invention.

TABLE 2

| Layers | Materials |
|---|---|
| Three heat spreading layers 220 | Cu metal sheets |
| Protection layer 210 | adhesive tape |
| Two heat insulating layers 230 with | Polymeric regions 250 are |
| polymeric regions 250 and void | pressure sensitive adhesives and |
| regions 240 | void regions 240 include air. |
| Adhesive layer 2100 | double coated adhesive tape |

The heat spreading layers 220 may be commercially available Cu sheet or foil. Preferably the Cu sheet or foil is less than about 100 μm in thickness and is selected so that total thickness of the heating spreading tape 100 can be as thin as desired. Cu sheets can preferably have a thickness from 18 to 35 μm, such as type EFR1YH(35 μm) Cu foil, commercially available from “ChangChun” Company in Taiwan. Other Cu sheets familiar to those skilled in the art of heat spreading tapes can also be selected to use. The protection layer 210 and the adhesive layer 2100 can be prepared from materials known to those skilled in the art and are also commercially available. In one embodiment, the protective layer is prepared from the commercially available 12T16 type adhesive tape from 3M Company in St. Paul, Minn. In the example, the thickness of the prepared protective layer 210 ranges from approximately 15 μm to approximately 25 μm. In another embodiment, the adhesive layer 2100 can be the double-sided coating tape as described above and particularly an acrylic thermally conductive tape for better heat transfer at the hot point 8. Without imposing any limitation; the thickness of the adhesive layer 2100 can range from approximately 20 μm to approximately 150 μm. In one example, the adhesive layer is prepared from 8003 type double-sided coating tape, and thickness thereof is approximately 30 μm. The 8003 type double-sided coating tape is commercially available from 3M Company in St. Paul, Minn.

The heat insulating layer 230 can have thickness from about 8 to about 100 μm as described above for previous embodiment of the invention. Preferably, heat insulating layer 230 may have a thickness ranging from about 8 to about 30 μm. The material selection of the heat insulating layer 230 of the second embodiment of the present invention can be similar to those explained for the first embodiment of the present invention. Also, lamination of layers can be made in a similar way as well. The heat insulating layer 230 may include an adhesive rubber. Similar to the previous discussion, the polymeric region 250 of heat insulating layer 230 can be selected from materials with low thermal conductivity and may be adapted to adhesively bond to other layers. In one aspect, the polymeric region 250 may be an adhesive. The adhesive may be at least one of a thermoset adhesive, pressure sensitive adhesive, thermoplastic elastomer adhesive and hot melt adhesive, pressure sensitive adhesives being preferred. The adhesive may include at least one of rubber adhesive, e.g. rubber pressure sensitive adhesive, acrylic adhesive, polyurethane adhesive, polyimide adhesive, silicone adhesive, epoxy adhesive and combinations thereof. For example, the adhesive of polymeric region 250 may be a rubber pressure sensitive adhesive or an acrylic pressure sensitive adhesive. As an example, a type 8003 polymeric acrylic adhesive tape commercially available from 3M Company, St. Paul, Minn. can be used to prepare the heat insulating layer 230. In the example, the thickness of the heat insulating layers 230 can be about 30 micron.

The heat spreading tape 200 according to the second embodiment of the invention may have different numbers of heat spreading layers 220, e.g. different numbers of Cu sheet or foil, and heat insulating layers 230, so that the total number of layers and the tape thickness may change accordingly. Several samples have been made with different numbers of heat spreading layers 220, wherein the heat spreading layer is Cu, and heat insulating layers 230 to compare performance.

Table 3 shows test results of thermal resistance comparison among the alternative heat spreading tapes 200 according to the present invention. The corresponding examples have different numbers of heat spreading layers 220, fabricated from Cu, and heat insulating layers 230, with void regions 240 (which include air) defined by polymeric regions 250. Example 2 has three Cu metal layers as heat spreading layers 220 and two heat insulating layers 230. Example 3 has two Cu metal layers as heat spreading layer 220 and one heat insulating layer 230. Example 4 has one Cu metal layer as heat spreading layer 220 and one heat insulating layer 230. Comparative Example 2 has one Cu metal layer, without an air gap, as the heat spreading layer and no heat insulating layer. Each sample has the dimensions of 40 mm×40 mm. The test instrument and method are the same as that used for the first embodiment of the present invention.

TABLE 3

| | | Thermal |
|---|---|---|
| | Total | Impedance of |
| | thickness | Z-direction |
| | (μm) | (° C. *cm²/W) |
| Example 2 (three Cu metal layers and | 150 | 11.50 |
| two heat insulating layers with void | | |
| regions and adhesive layer 2100 | | |
| Example 3 (two Cu metal layers and one | 190 | 11.95 |
| heat insulating layer with void regions | | |
| and adhesive layer 2100) | | |
| Example 4(one Cu metal layer and one | 60 | 6.58 |
| heat insulating layer with void regions) | | |
| Comparative Example 2 (one Cu metal | 60 | 2.91 |
| layer, no heat insulating layer) | | |

The data of Table 3 reveals that, Examples 2-4, with heat insulating layer(s) 230 having void region(s) 240, have higher thermal impedance than Comparative Example 6, which has a single heat spreading layer and does not have a heat insulating layer. Also, the data reveals that Examples 2 and 3, with multiple Cu metal layers as the heat spreading layers and multiple heat insulating layers, can achieve higher thermal impedance than Example 4, which has a single heat spreading layer and heat insulating layer.

Table 4 shows test results to compare thermal impedance of another heat spreading tape, Example 5, with multiple Cu metal layers as the heat spreading layers and multiple heat insulating layers according to the present invention, and Comparative Example 3, a heat spreading tape having multiple Cu metal layers as the heat spreading layers, without any heat insulating layers. Specifically, both Examples have the same dimensions and are tested under the same conditions. The adhesive layer 2100 in Example 5 is a foam tape.

TABLE 4

| | | Thermal |
|---|---|---|
| | Total | Impedance of |
| | Thickness | Z-direction |
| | (μm) | (° C. *cm²/W) |
| Example 5 with air structure (three Cu | 320 | 28.25 |
| metal layers as the heat spreading layers | | |
| and two heat insulating layers with void | | |
| regions and as adhesive layer 2100) | | |
| Comparative Example 3 without air | 300 | 16.14 |
| structure (three Cu metal layers as the | | |
| heat spreading layer and no heat | | |
| insulating layer) | | |

Example 5 and Comparative Example 3 have almost the same thickness. The data of Table 4 shows Example 5 has a higher thermal impedance than the Comparative Example 3.

Alternatively, regarding the multi-layer heat spreading tape 200 according to the second embodiment of the present invention, different arrangements of these layers in the multilayer heat spreading tape 200 may be adopted. For example, the adhesive layer 2100 may be a thermal conductive tape layer. On the other hand, the adhesive layer 2100 and Cu metal layer 220 may be removed, while using the rest of multi-layer heat spreading tape 200 on an outer shell, rather than a hot spot, such that, when in use, the outer shell of the tablet, notebook, smart phone, or TV may be attached directly by the heat spreading layer 230 of the multi-layer heat spreading tape 200. Furthermore, the array of void regions 240 in the heat spreading layer 230 also may adopt different layouts (see FIGS. 6a-6c and FIGS. 7a and 7b).

### Third Embodiment

A third embodiment of the heat spreading tape 300 is shown in FIGS. 8 and 9. The heat spreading tape 300 has heat insulating layer(s) 330 which includes void regions 340, defined by polymeric regions 350, sandwiched between two adhesive sheets 3301. The polymeric regions comprise at least a non-adhesive material. The heat spreading tape 300, according to the third embodiment of this invention, is in a multi-layer configuration. Specifically, the heat spreading tape 300 includes (i) a protection layer 310, which can be a single adhesive tape, for support and protection, (ii) three heat spreading layers 320 adapted for heat dissipation, which can be Cu metal, and (iii) three heat insulating layers 330 adapted as heat transfer barriers and adhesively laminated to heat spreading layers 320. As shown in FIG. 8, the three heat insulating layers 330 and the three heat spreading layers 320 are alternately arranged with one another. Void regions 340, which may include one or more gases, e.g. air, nitrogen, and carbon dioxide, are formed in and defined by polymeric regions 350 of the heat insulating layer 330 and are adapted for acting as heat barriers in the Z-direction, i.e. through the thickness of the heat insulating layer 330.

FIG. 9 shows schematic view of one heat insulating layer 330 of heat spreading tape 300 according to the third embodiment of the present invention. Specifically, the polymeric regions 350 of heat insulating layer 330 include a non-adhesive layer and two adhesive sheets 3301. The non-adhesive layer is positioned between and adhesively attached to the two adhesive sheets 3301, and void regions 340 are formed in the non-adhesive layer of polymeric region 350. Here, the non-adhesive layer is a foam material. The two adhesive sheets 3301 can be acrylic adhesive sheets adhered to both sides of the foam material. The void regions 340 are formed in the foam material of polymeric regions 350 and the arrow indicates the possible heat flow in the foam material. It is noted that, void regions 340 may either be gas pores formed in the foam material, or may be other available void structures (for example, gaps, channels, pores, holes, grooves, etc. . . . ) deliberately processed in the foam material. Foam materials with void structures known in the prior art can be selected and used as void structures within the polymeric regions 350. The thickness of the non-adhesive layer such as the foam material layer can range from approximately 100 μm to approximately 300 μm, and the size of the void regions 340 can range from approximately 2 μm to approximately 50 μm, depending on the foam material. However, in some examples, the size of the void regions 340 can range from approximately 20 μm to approximately 50 μm. Those skilled in the art can select the foam materials with different amounts and sizes of void regions as required to prepare the heat insulating layer 330 with the polymeric regions 350 and the void regions 340 in the embodiment. Therefore, the void regions 340 can have different total volumes. For example, the commercially available 4914 type foam material, from 3M Company in St. Paul, Minn., can be used for preparing the heat insulating layer 330. In this example, the thickness of the polymeric region 350 prepared can be approximately 250 μm, and density of the foam material is 0.90 g/cm³, which provides the void regions 340 with the volume percentage ranging from approximately 22% to 24% in the polymeric region 350. The foam materials with different thicknesses and foam material densities can be selected as required. The void regions 340 in FIG. 9 are spheres but do not necessarily have to be sphere shaped. However, the typical shapes of the void regions are sphere shapes. Protection layer 310, heat spreading layers 320 and others not detailed here can be referred and understood from previous embodiments already disclosed.

Without limitation to possible application, the heat spreading tape 300 in FIG. 8 is preferred to be used to attach to an outer shell 9 in FIG. 8 for heat insulation. In such application, the adhesive sheets 3301 of heat insulating layer 330 can attach to the outer shell 9. The protection layer 310 is preferably an electrical insulating and heat insulation layer for better protection.

### Fourth Embodiment

A fourth embodiment of a heat spreading tape 400 is shown in FIG. 10. Specifically, the heat spreading tape 400 includes (i) a protection layer 410, which may be an adhesive tape, (ii) a heat spreading layer 420, which can be metal or graphite sheet or foil, for heat dissipation, (iii) a heat insulating layer 430 adapted for purpose of providing a heat transfer barrier and (iv) a second heat insulating layer 460 for heat insulation, wherein void regions 440 are formed in the heat insulating layer 430 and are adapted for acting as heat transfer barriers in a Z-direction, i.e. through the thickness of the heat insulating layer 430.

Without limitation to possible application, the heat spreading tape 400 in FIG. 10 is preferred to be used to attach to a hot spot 8 for heat spreading. In such application, the protection layer 410 can be an adhesive tape known in the art to attach heat spreading tape 400 to hot spot 8. In one embodiment, the second heat insulating layer 460 is preferably an electrical insulating and heat insulating material known in the art, for better protection. Using thermally conductive metals such as copper and aluminum as the heat spreading layer 420 and using an adhesive or foam material to form the heat insulating layer 430 with the polymeric region 450 and the void region 440, both the heat spreading layer 420 and the heat insulating layer 430 can comprise single-layer and multi-layer tape structure as described in the above embodiments. In one example, polyamide foam material or other foam material of similar materials can be used for preparing the heat insulating layer 430 with thickness ranging from approximately 200 μm to 300 μm. In the example, the polyamide foam material provides the polymeric region 450, and the void region 440 is also formed therein. The specific sizes, volumes and structures of the polymeric region 450 and the void region 440 are dependent on the materials and methods for preparing polyamide foam and can vary. For example, the volume of the gaps and pores of the void region 440 provided in the foam material can range from approximately 60% to approximately 90% of the total volume of the foam materials, and the average size of the gaps and pores can range from approximately 2.0 μm to approximately 2.5 μm. Similar to the above embodiments, the void region 440 can contain air or air and one or more gases selected from nitrogen and carbon dioxide. The example shows that the foam material having more small gaps than those in the third embodiment can be used for preparing the heat insulating layer 430. In another embodiment, the heat spreading layer 420 can be prepared from such materials as 3M 9876 type metallic foil from the 3M Company in St. Paul, Minn. All the layers can be laminated as described above.

In accordance with the present invention, polymeric materials such as adhesives having low thermal conductivity, about 0.2 W/m·K or lower, are selected to prepare the heat insulating layer with void regions as air has a very low thermal conductivity, about 0.023 W/m·K, the void regions may include air, one or more gases, e.g. air, nitrogen, and carbon dioxide. Accordingly, void regions are introduced into the heat spreading tape of this invention to act as “heat transfer barriers” and form a heat insulating layer, typically in the Z-direction i.e. through the thickness of the heat spreading tape. Further, although graphite may be used as a heat spreading layer, more suitable heat spreading materials, e.g. metal, ceramics, and the like, may be used in the manufacture of the heat spreading layer of the heat spreading tape, in accordance with the present invention. Furthermore, a multi-layer laminated technology is adopted in the present invention, to improve the heat dissipation performance of the prior art heat spreading tape, i.e., good heat dissipation in the X-Y directions, while improving the heat transfer barrier characteristics in the Z-direction.

Although several embodiments have been shown and described, it would be appreciated by those skilled in the art that feature(s) in one embodiment will be interchangeable with those in another embodiment and, various changes or modifications may be made in these embodiments without departing from the principles and spirit of the disclosure, the scope of which is defined in the claims and their equivalents.

What is claimed is:

1. A heat spreading tape, comprising:
a heat spreading layer;
a heat insulating layer, adhesively attached to the heat spreading layer, wherein the heat insulating layer comprises at least one polymeric region and at least one void region, wherein the at least one polymeric region comprises an adhesive.

2. The heat spreading tape according to claim 1, further comprising a protection layer attached to the heat spreading layer.

3. The heat spreading tape according to claim 2, wherein the protection layer is an electrical insulating layer.

4. The heat spreading tape according to claim 2, wherein the protection layer is an acrylic adhesive tape.

5. (canceled)

6. (canceled)

7. The heat spreading tape according to claim 1, further comprising an adhesive layer attached to the heat spreading layer.

8. The heat spreading tape according to claim 7, wherein the adhesive layer has a thickness ranging from about 20 μm to about 150 μm.

9. The heat spreading tape according to claim 1, further comprising a protection layer attached to the heat insulating layer.

10. The heat spreading tape according to claim 1, wherein the void region is formed in, and defined by, the at least one polymeric region.

11. The heat spreading tape according to claim 1, wherein the void region contains one or more gases selected from air, nitrogen, and carbon dioxide.

12. (canceled)

13. The heat spreading tape according to claim 1, wherein the adhesive is selected from one of a: rubber pressure sensitive adhesive, acrylic adhesive, polyurethane adhesive, polyimide adhesive, silicone adhesive, epoxy adhesive and combinations thereof.

14. The heat spreading tape according to claim 1, wherein the void region may have a structure of at least one of gap, channels, pores, holes, grooves, and combinations thereof.

15. The heat spreading tape according to claim 1, wherein the void region has a width of about 0.1 mm to about 5 mm and a height of about 2 μm to about 50 μm.

16. The heat spreading tape according to claim 1, wherein the heat insulating layer further includes two adhesive sheets, wherein the polymeric region comprises at least a non-adhesive layer positioned between and adhesively attached to the two adhesive sheets, and wherein the void region is formed in the non-adhesive layer.

17. The heat spreading tape according to claim 16, wherein the non-adhesive layer is a foam with a plurality of void regions.

18. The heat spreading tape according to claim 17, wherein the plurality of void regions have sizes ranging from about 2 μm to about 50 μm.

19. The heat spreading tape according to claim 1, wherein a total volume of void regions formed in the heat insulating layer is from about 22% to about 90% of a volume of the heat insulating layer.

20. The heat spreading tape according to claim 1, wherein a total volume of void regions formed in the heat insulating layer is about one third of a volume of the heat insulating layer.

21. The heat spreading tape according to claim 1, wherein a total thickness of the heat spreading tape is from about 0.01 mm to about 0.4 mm.

22. The heat spreading tape according to claim 1, further comprising a plurality of heat spreading layers and/or a plurality of heat insulating layers, wherein the heat spreading layers and the heat insulating layers are alternately arranged with each other.

23. The heat spreading tape according to claim 1, wherein the heat spreading layer comprises at least one of: metal, ceramic, graphite, graphene, composite made of thermally conductive particles and polymers, and combinations thereof.

24. (canceled)

25. (canceled)
